(19) United States
(12) Patent Application Publication
(10) Pub. No.: US 2006/0127817 A1
(43) Pub. Date: Jun. 15, 2006

(54) In-line fabrication of curved surface transistors

(75) Inventors: Sujatha Ramanujan, Pittsford, NY (US); Yongtaek Hong, Webster, NY (US)

Correspondence Address: Mark G. Bocchetti;Patent Legal Staff, Eastman Kodak Company, 343 State Street, Rochester, NY, 14650-2201, US

(73) Assignee: Eastman Kodak Company

(21) Appl. No.: 11/009,801

(22) Filed: Dec. 10, 2004

(51) Int. Cl. G03F 7/00

(52) U.S. Cl. 430/320

(57) ABSTRACT

A method for in-line fabrication of curved surface transistors (10) forms a flexible substrate (12) into a predetermined shape. A first passivation layer (14) is deposited. A first metal layer (16) in a first pattern is deposited. An insulator layer (18) in a second pattern is deposited. A first semiconductor (20) in a third pattern and a second semiconductor (22) in a fourth pattern are deposited. A second metal layer (24) in a fifth pattern is deposited. A second passivation layer (28) in a sixth pattern is deposited.

### CROSS REFERENCE TO RELATED APPLICATIONS

Reference is made to commonly-assigned copending U.S. patent application Ser. No. 10/881,301, filed Jun. 30, 2004, entitled FORMING ELECTRICAL CONDUCTORS ON A SUBSTRATE, by Yang et al.; the disclosure of which is incorporated herein.

### FIELD OF THE INVENTION

This invention relates in general to the production of thin film transistors (TFTs) and in particular to fabrication of transistors on a curved flexible surface.

### BACKGROUND OF THE INVENTION

Manufacturing of thin film transistors (TFTs) is a complicated, time consuming, expensive process. The typical process involves fabrication of multiple layers on a batch-by-batch photolithography basis by a glass substrate. To reduce the manufacturing cost, some of photolithography steps in the TFT fabrication process can be replaced by a low-cost, printing method. U.S. Pat. No. 6,080,606 (Gleskova et al.) uses a toner-based printing method for photomask and etch or lift-off mask on glass substrates for back plane of low-cost, large-area LCD display applications. U.S. Pat. No. 6,274,412 (Kydd et al.) uses an electrostatic printing method for gate, data, and possibly indium tin oxide pixel on glass substrates for back planes for displays, detectors, and scanners applications. U.S. Patent Application Publication Nos. 2003/0027082 and 2004/0002225 (both to Wong et al.) use an inkjet printing method for etch-mask that is based on wax and surface treatment. All the printing methods for the TFT fabrication are applied on flat, not-curved substrates.

Some uses require fabrication of TFTs on a flexible, curved background. TFTs on flexible curved surfaces have important uses in many fields, for example in the medical field, particularly mammography. Currently, fabrication of TFTs on a flexible, curved surface can be accomplished by manufacturing the TFT on a flexible substrate and bending it to the desired shape as P. I. Hsu reported in “Thin-film transistor circuits on large-area spherical surfaces,” Applied Physics Letters, Vol. 81, No. 9, pp. 1723-1725, 2002. A drawback with this type of manufacturing is that the thin metal layers that comprise the TFT are often cracked or broken during the bending process. In addition, all the thin film layers of TFT are patterned in island forms to reduce any film strain effect on TFT performance and cracks of the thin film itself. This method, while an improvement, still has associated cracking problems.

An object of this invention is to provide a predetermined shaped substrate which results in less stress and cracking of thin-film devices. Another object is to develop a printing apparatus for printing onto curved (hollow) surface of the substrate (metal and etch-mask printing) for low-cost process. Yet another object is to provide a improved position accuracy and printing speed with drop-on-demand or continuous printing method to improve process speed and yield.

### SUMMARY OF THE INVENTION

Briefly, according to one aspect of the present invention a method for in-line fabrication of curved surface transistors forms a flexible substrate into a predetermined shape. A first passivation layer is deposited and a first metal layer in a first pattern is deposited. An insulator layer in a second pattern is deposited. A first semiconductor in a third pattern and a second semiconductor in a fourth pattern are deposited. A second metal layer in a fifth pattern is deposited and a second passivation layer in a sixth pattern is deposited.

The invention and its objects and advantages will become more apparent in the detailed description of the preferred embodiment presented below.

### BRIEF DESCRIPTION OF THE DRAWINGS

FIG. 1 cross-section of a typical back-channel-etch-type amorphous silicon thin-film transistor.

FIG. 2 is a process flow chart for a conventional photolithography-based amorphous silicon thin-film transistor.

FIGS. 3a-3f are cross-sections of each step of the conventional photolithography-based amorphous silicon thin-film transistor process flow.

FIG. 4 is a process flow chart for a hybrid (conventional and printed) amorphous silicon thin-film transistor according to the present invention.

FIG. 5 shows examples of the shapes of the pre-curved (spherical and cylindrical) substrate.

FIG. 6 shows a side schematic view of a printing method based on a moving inkjet printing head according to the present invention.

FIG. 7 shows a side schematic view of drop placement to the substrate position according to the present invention.

FIG. 8 shows a side schematic view of nozzle placement according to an embodiment present invention.

FIG. 9 shows a side schematic view of a curved printhead according to the present invention.

FIG. 10 shows a schematic view of an embodiment for regulating the temperature of the substrate by heating the mount.

FIG. 11 shows schematic view of an embodiment for using a heater such as a laser to heat regions of the substrate where the pattern will be formed.

FIG. 12 shows schematic view of an embodiment for a wax or polymeric mask during patterning according to the present invention.

FIG. 13 shows a schematic view of an embodiment for a proximity mask according to the present invention.

FIG. 14 shows a side schematic view of a proximity mask such as a moving bar along an axis where a drip may occur.

FIG. 15 shows a schematic example of a composite process according to the present invention.

FIG. 16 shows a schematic of an alternate process to contain the process within a curved enclosure.

### DETAILED DESCRIPTION OF THE INVENTION

The present invention will be directed in particular to elements forming part of, or in cooperation more directly with the apparatus in accordance with the present invention. It is to be understood that elements not specifically shown or described may take various forms well known to those skilled in the art.

Description of Standard a-Si Process

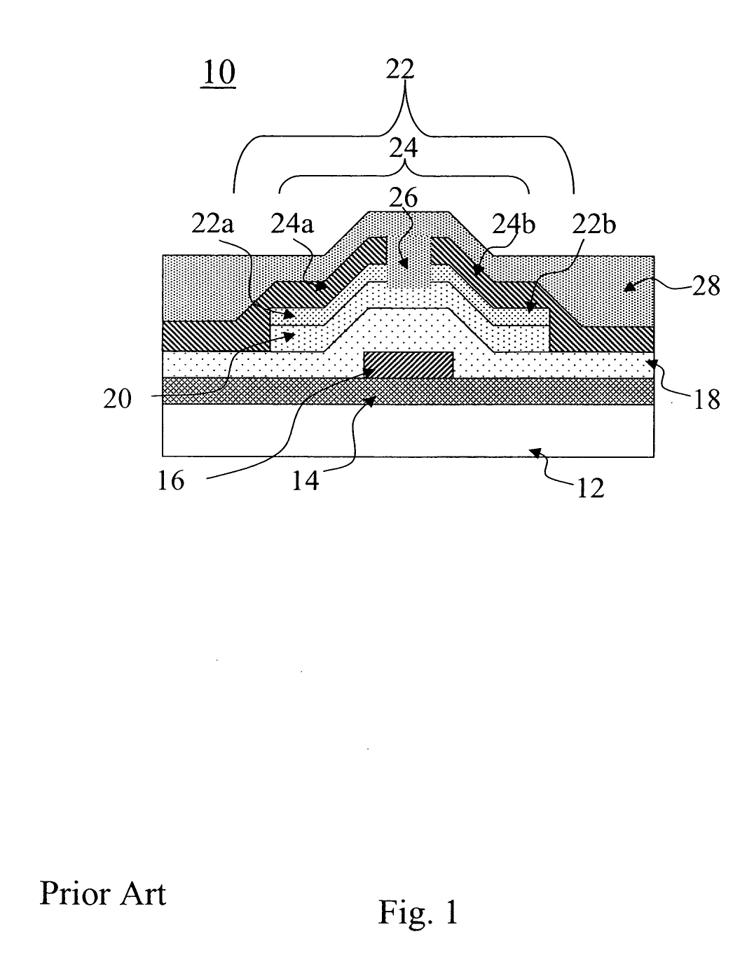

A standard back-channel-etch-type (BCE) hydrogenated amorphous silicon thin-film transistor (a-Si:H TFT) fabrication process consists of four mask steps: first metal layer pattern (gate), first and second semiconductor layer pattern (active island), insulator layer pattern (gate via), and second metal layer pattern (source and drain). A cross-section view of a typical BCE a-Si:H TFT fabricated on a flat substrate is shown in FIG. 1, 10. The typical BCE a-Si:H TFT has a first passivation layer 14, a first patterned metal layer 16, a patterned insulator layer 18, a first semiconductor layer 20, a second semiconductor layer 22a and 22b, a patterned second metal layer 24a and 24b, an etched back channel area 26, and a second patterned passivation layer 28 on a flat substrate 12.

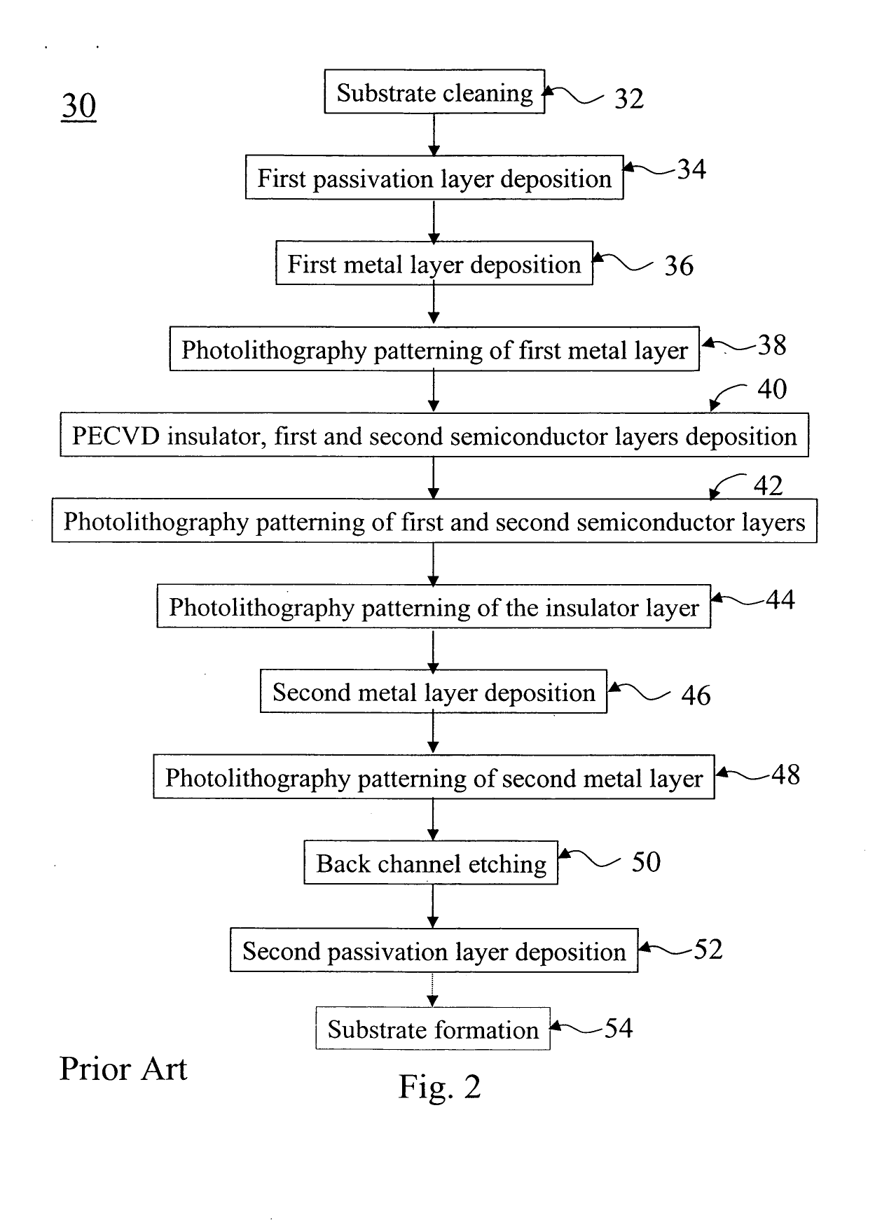

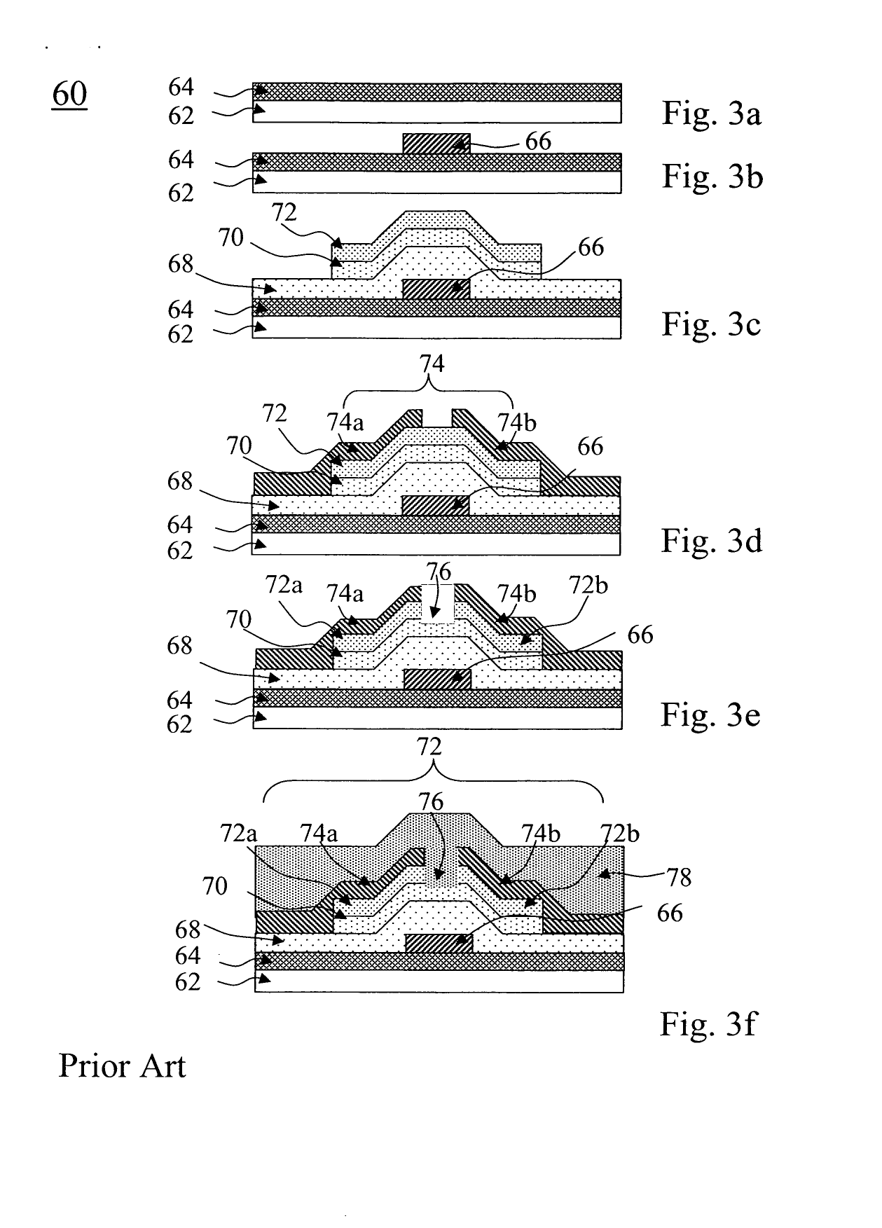

A detailed process flow 30 is described in FIG. 2, and corresponding cross-section views 60 are described in FIGS. 3a-3f. After the substrate 62 is cleaned 32, a first passivation layer 64 is deposited 34. See FIGS. 3a and 3b. The first passivation layer 64 can be deposited by either vacuum or solution process. Inorganic, such as amorphous silicon oxide (a-SiOx) or amorphous silicon nitride (a-SiNx), or organic, such as sol-gel or polymer, materials can be used for the first passivation layer 64. If the substrate 62 is a conventional glass substrate (e.g., Corning 1737), this first passivation layer process 34 can be omitted because the glass substrate usually provides both smooth surface roughness and perfect electrical insulation without any additional passivation layer 64.

The first metal layer 66 is deposited 36 on the first passivation layer 64 by thermal or electron-beam evaporation, or sputtering methods. The deposited first metal layer 66 is patterned by a conventional photolithography method 38, which consists of photoresist (PR) material coating, soft-bake curing of coated PR, ultra-violet (UV) light exposure through a photo-mask that has a specific pattern, development in PR developer solution, hard-bake curing of patterned PR, etching of the first metal layer by using the patterned PR as an etch mask, and removing of PR patterns that has been used as etch masks. The first metal layer 66 can be etched by either a wet-etching or dry-etching method, preferably, wet-etching method. The patterned first metal layer is used as a gate for a conventional a-Si:H TFT, FIG. 3b (Mask #1, gate).

An insulator layer 68, first 70 and second 72 semiconductor layers are consecutively deposited by a chemical vapor deposition (CVD) method, preferably, a plasma enhanced CVD (PECVD) method 40. The insulator layer 68 acts as a gate dielectric layer, which is typically an a-SiOx layer, an a-SiNx layer, or double layer consisting of both layers. The first 70 and second 72 semiconductor layers are active and doped semiconductor layers, respectively. An electrically conducting channel is formed in the active semiconductor layer 70, especially close to the interface between the active semiconductor layer 70 and the insulator layer 68 when a positive bias voltage is applied to the first metal layer 16 with respective to one of the patterned second metal layers, 74a or 74b. The doped semiconductor layer 72 will provide an ohmic contact between the active semiconductor 20 and the following second metal layers 74a and 74b.

The deposited first 70 and second 72 semiconductor layers are patterned by the conventional photolithography method 42 that is described above in detail, FIG. 3c (Mask #2, active island). To etch both the first and second semiconductor layers, either wet-etching or dry-etching method can be used, preferably, dry plasma or reactive ion etching (RIE) method.

After the active island is formed, the insulator layer 68 is patterned by the conventional photolithography method 44 to open windows through the insulator layer 68, which is not shown in the cross-section views in FIGS. 3a-3f (Mask #3, gate via). The insulator layer 68 can be etched by either a wet-etching or dry-etching method. The gate via provides the first metal layer 66 with an electrical contact to either test probe for characterization of each device or the following second metal layer 74 for circuit formation that is composed of at least two TFTs.

A second metal layer 74 is deposited 46 by thermal or electron-beam evaporation, or sputtering methods. The deposited second metal layer 74 is patterned by the conventional photolithography method 48, FIG. 3d (Mask #4, source and drain). The second metal layer 74 can be etched by either a wet-etching or dry-etching method. If one of the patterned second metal layers 74a or 74b acts as a source of the TFT, the other patterned second metal layer will act as a drain of the TFT. By using the patterned second metal layer 74a and 74b as etch mask, the second semiconductor layer 72 is etched by dry plasma or RIE method 50, FIG. 3e. The patterned doped semiconductor layer 72a and 72b provides a good ohmic contact between second metal layer 74a and 74b and the active semiconductor layer 70. After the back channel etching process 50, a second passivation layer 78 is deposited 52, FIG. 3f. The same materials and the same deposition methods as the first passivation layer 64 can be used for the second passivation layer 78.

In FIG. 2, there is one more step for producing curved substrate formation 54. As described above, a typical a-Si:H TFT consists of several thin-film layers, which causes film cracks when the substrate is bent after the TFT process is finished. Therefore, Hsu et. al investigated mechanical strains and modification of conventional TFT process in combination of substrate modifications. “Thin-film transistor circuits on large-area spherical surfaces,” Applied Physics Letters, vol. 81, no. 9, pp. 1723-1725, and “Effects of Mechanical Strain on TFTs on Spherical Domes,” IEEE Transactions on Electron Devices, vol. 51, no. 3, pp. 371-377, 2004. They fabricated TFTs on bulging side of a spherical dome plastic substrate by using double layer of organic and inorganic gate dielectric materials, patterning the inorganic gate dielectric layer to protect continuous inorganic film from cracking, locating active islands on points with less stress, and modifying the flat substrate into spherical dome for interconnects. All the efforts made in their work are reducing stress that thin film layers undergo during substrate modifications. Also, all the processes used consume a lot of time in addition to the typical a-Si:H TFT process, which are not good for factory production or in-line process.

Hybrid Process

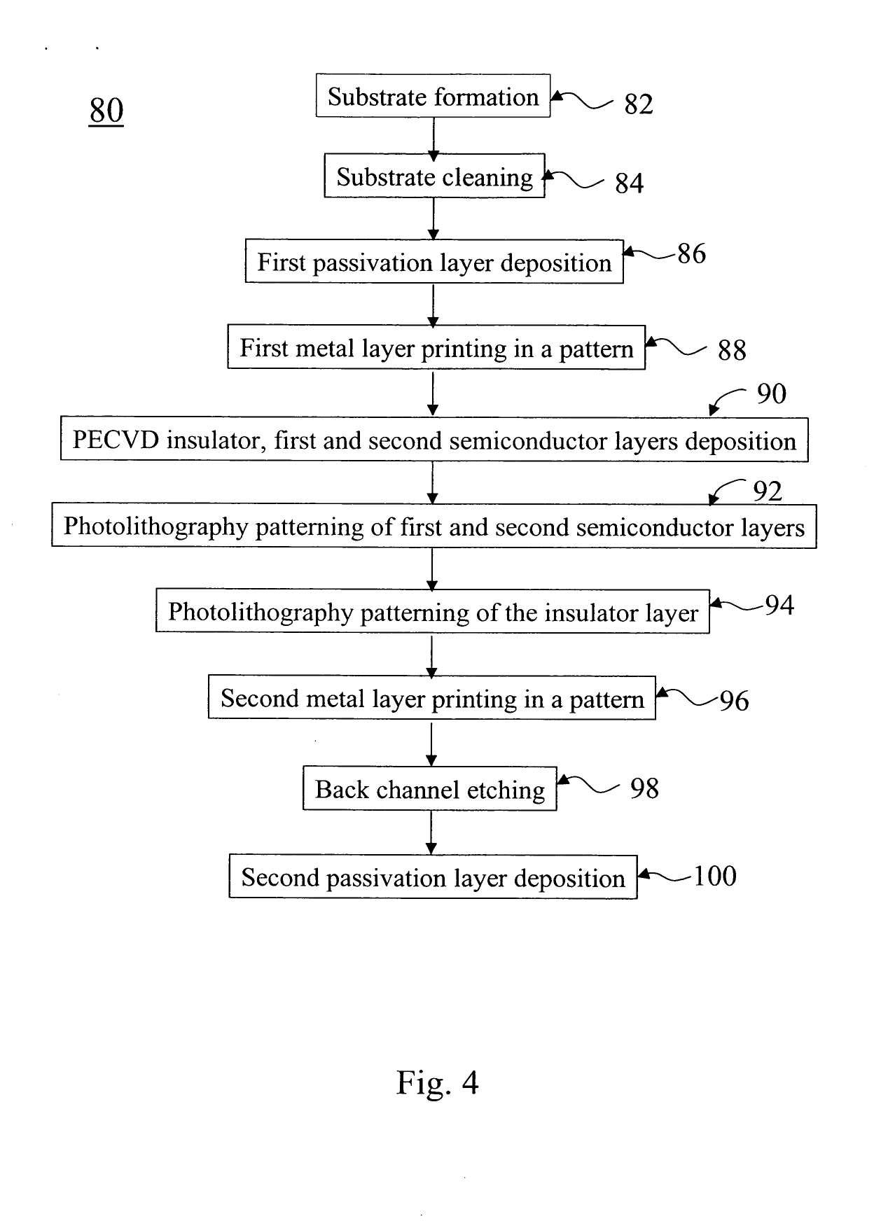

The present invention provides an apparatus for fabricating a-Si:H TFTs on pre-curved substrates, especially for printing all the metal layer patterns, which can be used in in-line curved (hollow) surface TFT process. Because conventional PEVCD and novel printing methods for a-Si:H TFT fabrication are combined, this process is called “hybrid a-Si:H TFT process” in the present invention. The details of the hybrid a-Si:H TFT process flow 80 are described in FIG. 4, wherein the processes are the same as the conventional a-Si:H TFT processes except for pre-formation of the substrate 82, printing the first and second metal layers 88 and 96.

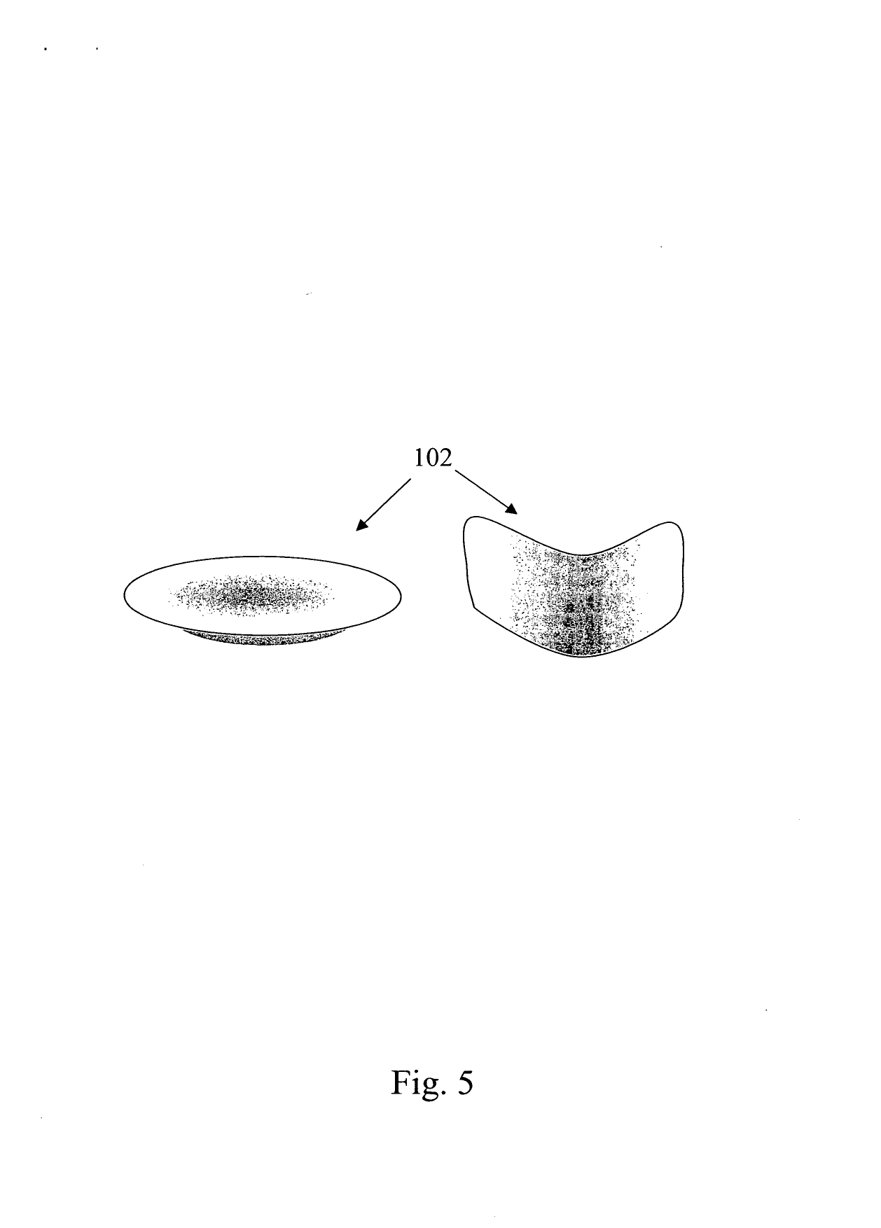

First, a substrate is formed into a pre-curved shape 82, which can be a spherical or a cylindrical form 102 as shown in FIG. 5. Choice of substrate proves to be an important part of process definition. As the substrate is expected to conform to a predefined radius of curvature, it is understood that the substrate of choice conform to the shape and maintain the form without breaking. Choices for such substrates include plastics such as Kapton, PEN, and PET. In the case of plastic the process temperature is considerably lower as to maintain the integrity of the substrate. In return, the plastic is widely conformable and the allowed curvature is often more dependent on the electronic materials and the front plane choice. In addition to plastics, metal substrates particular thin metals (foils) can be pressed and altered to fit the desired shape. Metal process temperatures are generally higher than plastics but still lower than glass.

In the case of particularly thin substrates, the base substrate may be mounted to a carrier substrate such as glass. The carrier substrate ensures that the surface profile is maintained during the deposition processes.

After cleaning 84 the pre-curved substrate 102, a first passivation layer is deposited 86. The first passivation layer is deposited by vacuum or solution process. On top of the first passivation layer, a first metal layer pattern is printed 88 by an inkjet printing based method, where drop-on-demand (DoD) or continuous stream printing head can be used.

On the printed first metal pattern, an insulator, a first semiconductor and a second semiconductor layer are consecutively deposited by CVD method, preferably by PECVD 90. The first and second semiconductor layers and the insulator layer are patterned by photolithography method 92 and 94. The second metal layer pattern is printed 96 by the same method as the first metal layer patterns 88. After the back channel etching 98 by using the patterned second metal layer as an etch mask, a second passivation layer is deposited 100 by the same method as the first passivation layer 86. The total number of required photolithography steps is reduced for the hybrid a-Si:H TFT process 80 because the photolithography steps for the first 66 and second 74 metal layer patterning in the conventional a-Si:H TFT process 30 are not needed. If this method is combined with the prior art (printing etch mask, U.S. Pat. No. 6,080,606; U.S. Patent Application Publication Nos. 2003/0027082 and 2004/0002225), all the conventional photolithography steps can be removed. In these prior arts, the active island was patterned by printing etch mask material on the second semiconductor and then etching the first and second semiconductor layers through the etch mask.

To produce finer feature pattern with printing method, wax mask (U.S. Patent Application Publication No. 2004/0002225 A1) can be used. In this method, the wax mask is printed on the blanket of material layers (metal, dielectric, or semiconductor layer) to be patterned. The printed wax mask is used as a negative resist for etch mask patterning; therefore, the space between printed wax patterns will determine the feature sizes of the patterns. Using this technique, feature sizes of devices smaller than the smallest droplet printed may be fabricated.

Another method for the finer feature pattern is polymeric mask lamination (“Invited Paper: Large area, High Performance OTFT Arrays,” Technical Digest of SID 2004, pp. 1192-1193, 2004). In this method, polymeric mask with negative images of patterns that is finer than those from directly printed material layer (metal, dielectric, or semiconductor layer) patterns is separately prepared. After it is laminated on the substrate, the material layer is printed through the polymeric mask, which will determine the feature sizes and enhance the accuracy of placement of printed droplets.

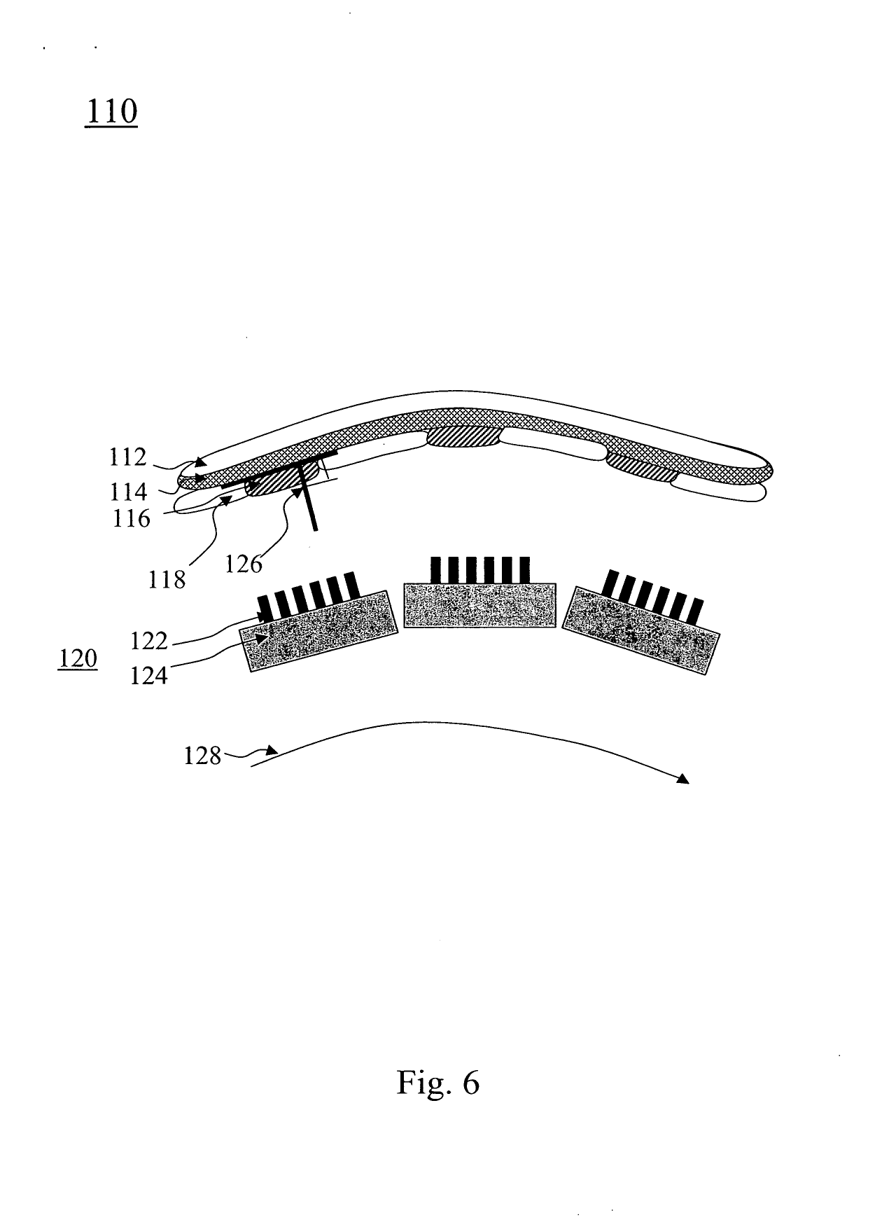

FIG. 6 is a cross-sectional view of the concave cup shown in FIG. 5, which shows a printing method 110 based on a moving inkjet head 120 for the first metal layer 116 on the pre-curved substrate 112 with a deposited first passivation layer 114. (Printhead 120 is shown in three sequential positions.) FIG. 6 shows the printhead 120 mounted below the pre-curved substrate 112.

The inkjet head 120 consists of one or more ink exits or nozzles 122 and one or more control elements 124. The inkjet head 120 can be either a DoD-type or a continuous stream-type printhead. Since this method is a solution based method, the drying property of the drops is very important for printed feature size. Therefore, the temperature of pre-curved substrate 112 can be accurately controlled to produce a desired feature size.

To accurately place the drops on the desired places of the pre-curved substrate 112, both the pre-curved substrate 112 and the printhead 120 can relatively moved and rotated; preferably the printhead 120 moves and rotates for the fixed pre-curved substrate 112 so that the printing drop direction is normal to the tangential of the curved surface 126 as shown in FIG. 6. The position of the pre-curved substrate 112 can be changed with respect to the printing drop directions for better containment of ink drips. For example, in a conventional printing process, the printhead is located on the printing surface so that the printing drop direction is from top to bottom. However, in the current invention, the printhead 120 can be located under the printing surface of the pre-curved substrate 112 so that the printing drop direction can be from bottom to top. In this case, FIG. 6 shows the front view of the positions of the printhead 120 and the pre-curved substrate 112. The printhead 120 can also be horizontally placed with respect to the printing surface of the pre-curved substrate 112 so that the printing drop direction can be horizontal. In this case FIG. 6 shows the top view of the positions of the printhead 120 and the pre-curved substrate 112. In all cases, a wax mask 118 can be printed before the first metal layer 116 is printed to better improve the ink placement and feature formation.

Trajectory Mapping

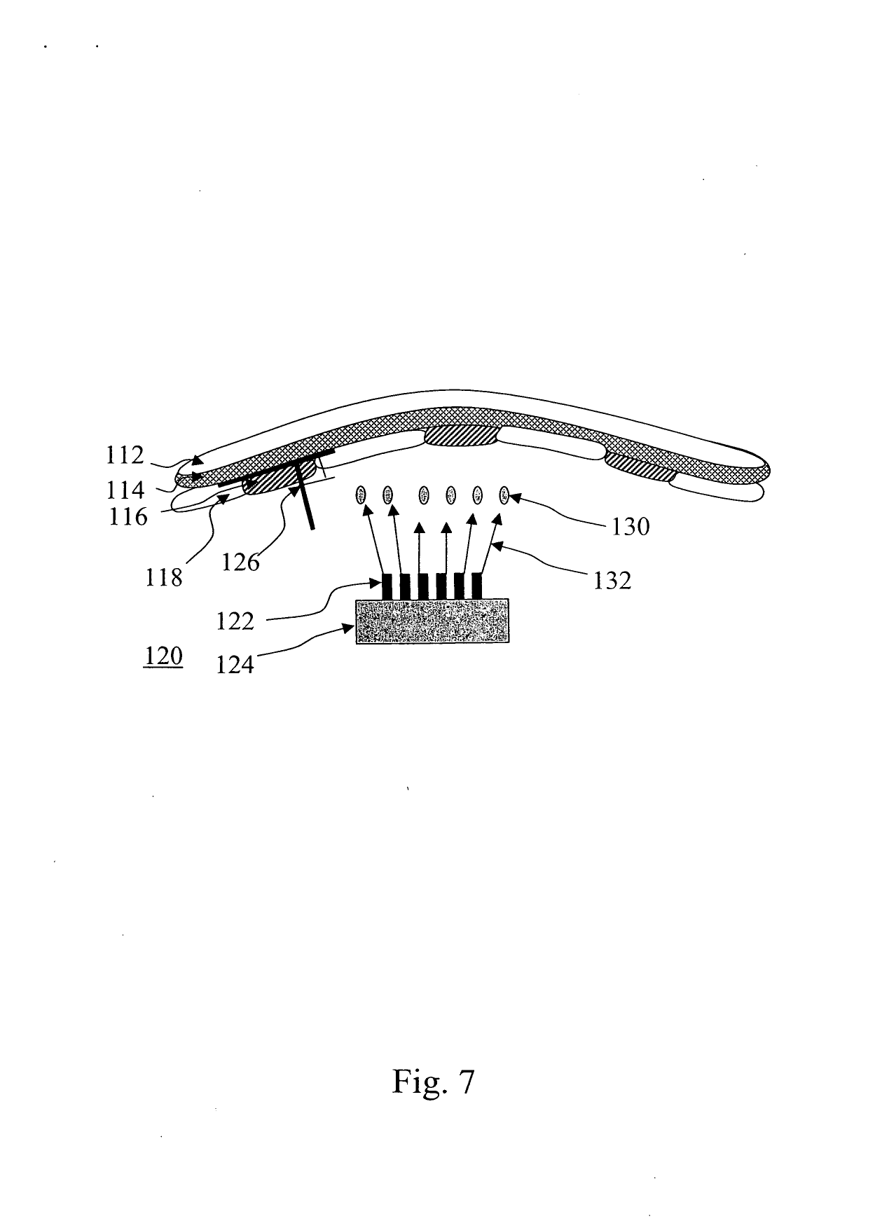

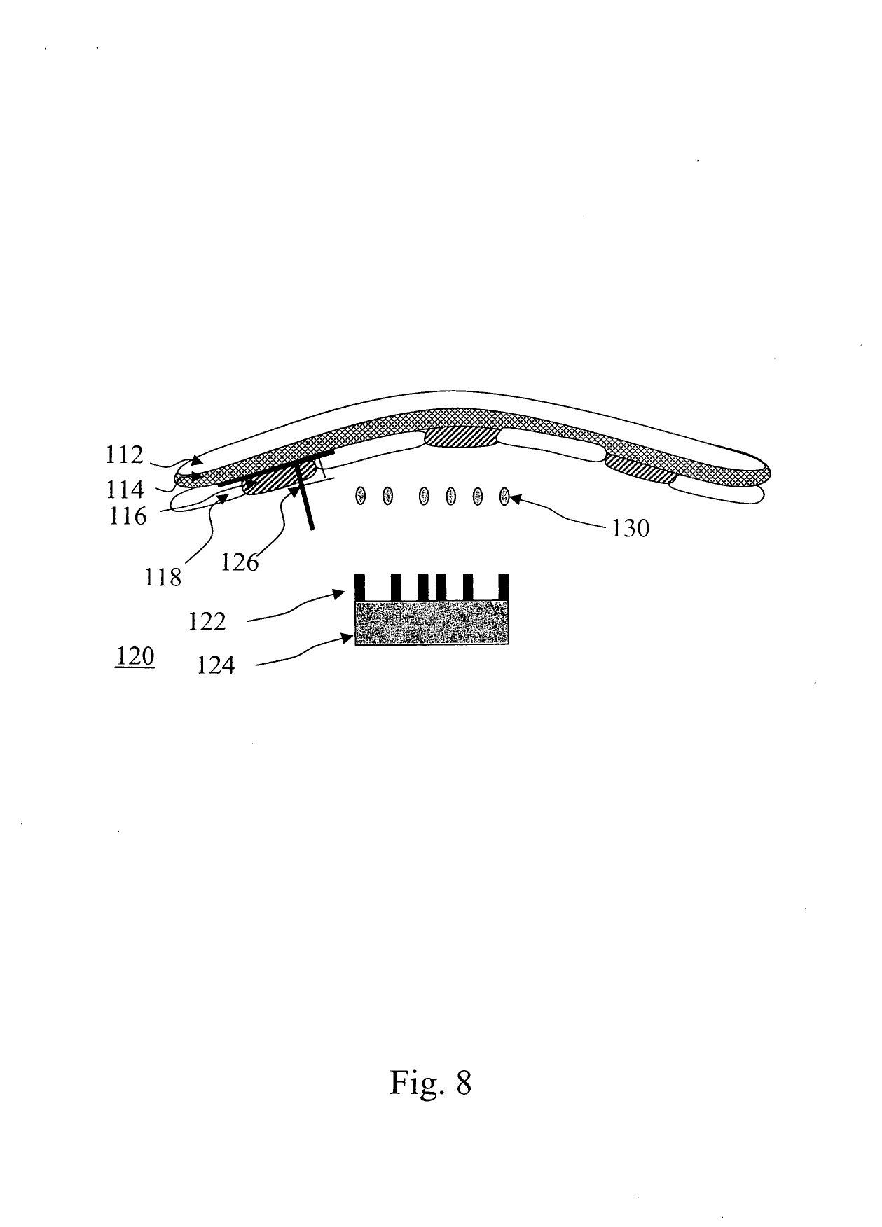

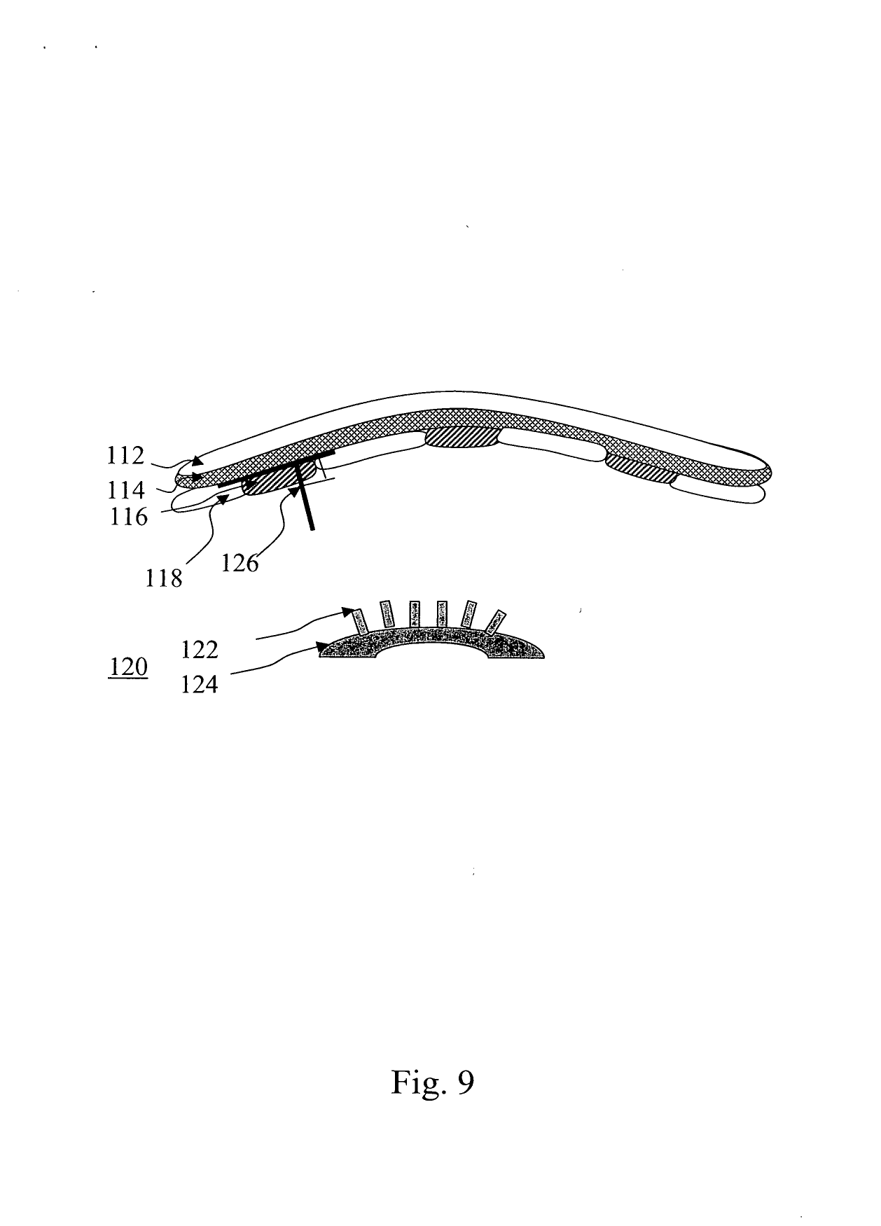

The printhead itself may follow a trajectory 128 defined by the curvature of the substrate in order to print the electronic material with regular features and sizes. An example of that trajectory 128 is shown in FIG. 6. Physical position of the head is not the only way to regulate drop position. The drop 130 deflection 132 from the printhead may be adjusted to account for curvature of the substrate and to ensure the drop placement be normal to the substrate position as is shown in FIG. 7. If the substrate is significantly curved, and the multi-nozzle printhead is straight, there may be a limit to how much drop placement error can be corrected by relative motion of the head to the substrate or the drop to the substrate. The nozzle placement may not be periodic but grouped by required placement as is shown in FIG. 8. In extreme cases it may be necessary for the printhead to be curved as well as is shown FIG. 9.

Drip Containment

When using solutions or liquids, there are several issues that need to be addressed. The first issue is drip containment. In the case of drop on demand inkjet printing, drip containment is required for those drops that do not adhere to the surface as intended. A drop that does not adhere can drip, or spread to unwanted areas of the backplane. The drop may also release completely from the substrate and land elsewhere in the deposition equipment or back on the inkjet head. All of these situations are highly undesirable.

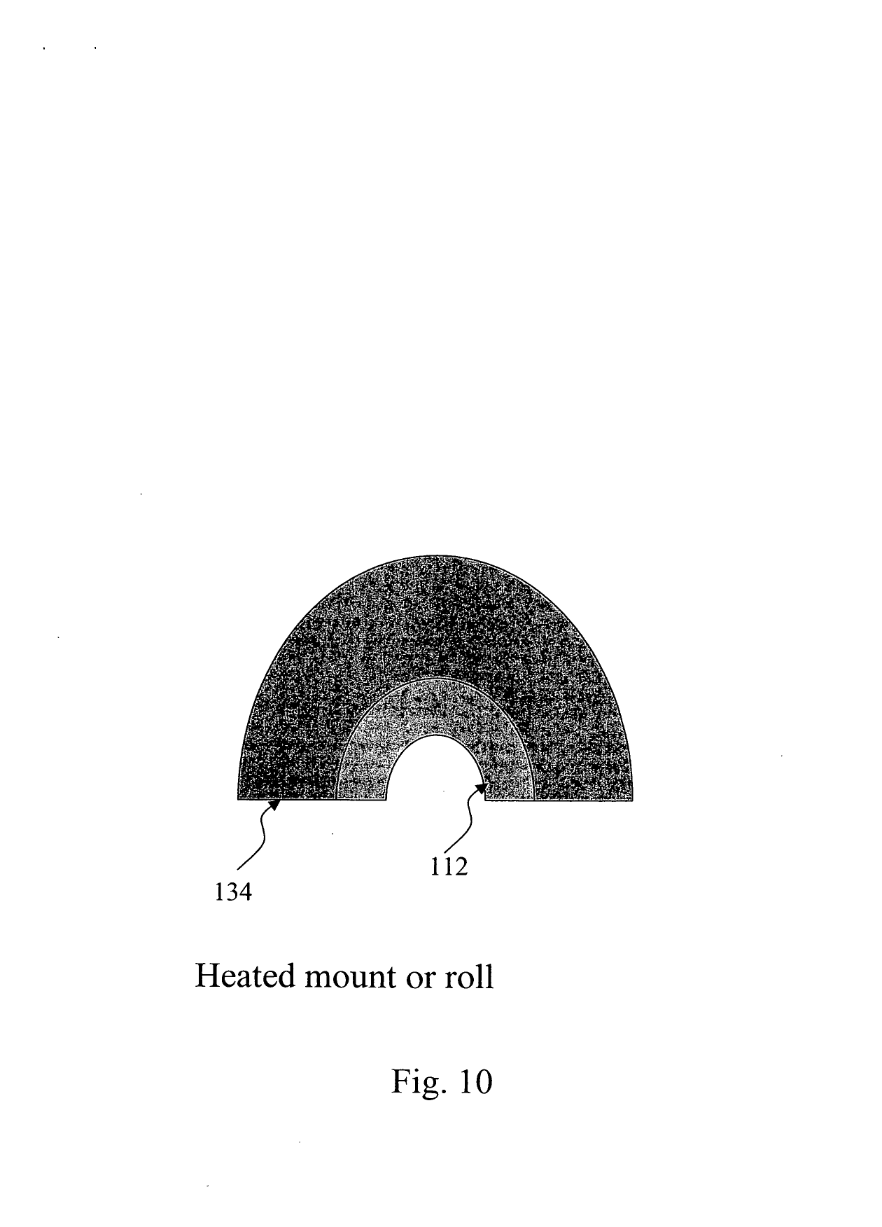

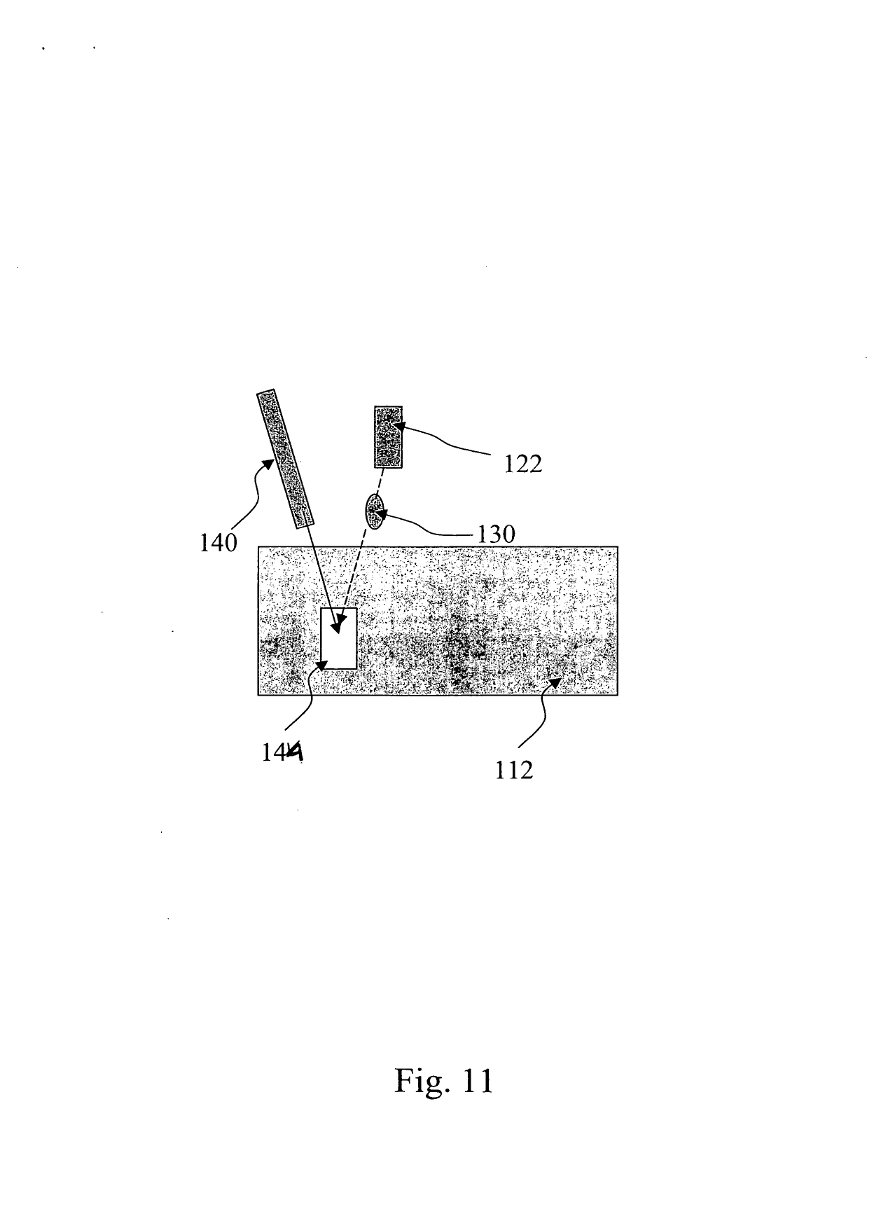

The most efficient method of drip containment is to simply place the drop where needed and ensure adhesion. One method for accomplishing this is to regulate the temperature of the substrate 112 by heating the mount 134 as is shown in FIG. 10. At sufficiently elevated temperatures, the drop may be annealed almost as soon as contact is made. Controlling the substrate temperature also ensures control over the distortion of the substrate and improves the yield of devices. One method to control the substrate temperature is to control the mount. Alternatively, a heater such as a laser 140 can heat regions of the substrate 112 where the pattern 144 is formed, as is shown FIG. 11. Another method is to control locally the surface of the web on which the substrate is traveling. Finally, one can control the ambient operating conditions.

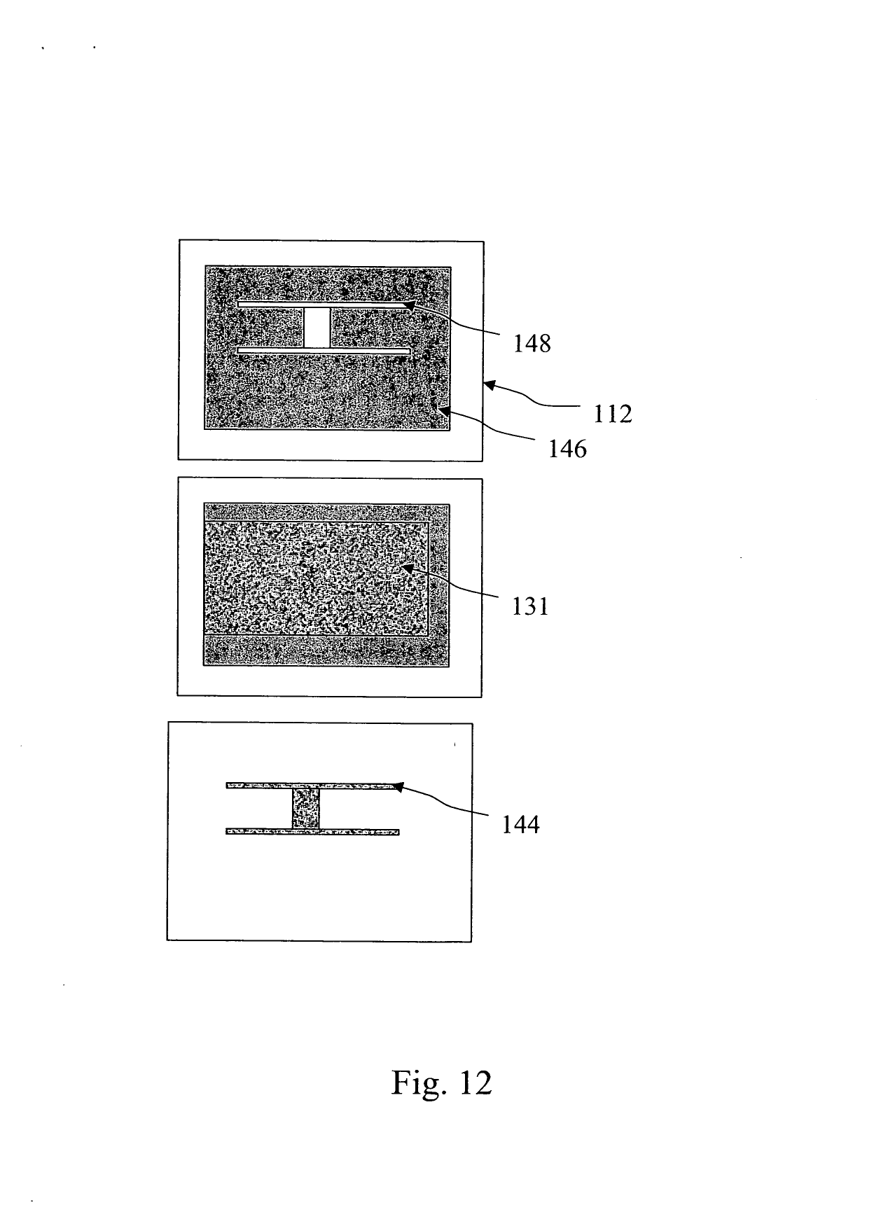

Another approach uses a barrier to contain the drop. If a mask is employed, the mask may act as a barrier preventing fluid from migrating to undesirable regions of the substrate. A drip containment max may be place in contact or in close proximity to the substrate. If a wax or polymeric mask is used during patterning, it may be left in place to contain drip, the process for which is shown in FIG. 12. In FIG. 12, the substrate 112 is in contact with the mask 146 exposing the relative image of the pattern 148. Ink 131 is deposited on the mask 146 and the region 148. Drop placement needs only to be confined to the general mask area. When the mask 146 is removed, the pattern 144 remains well defined on the substrate 112.

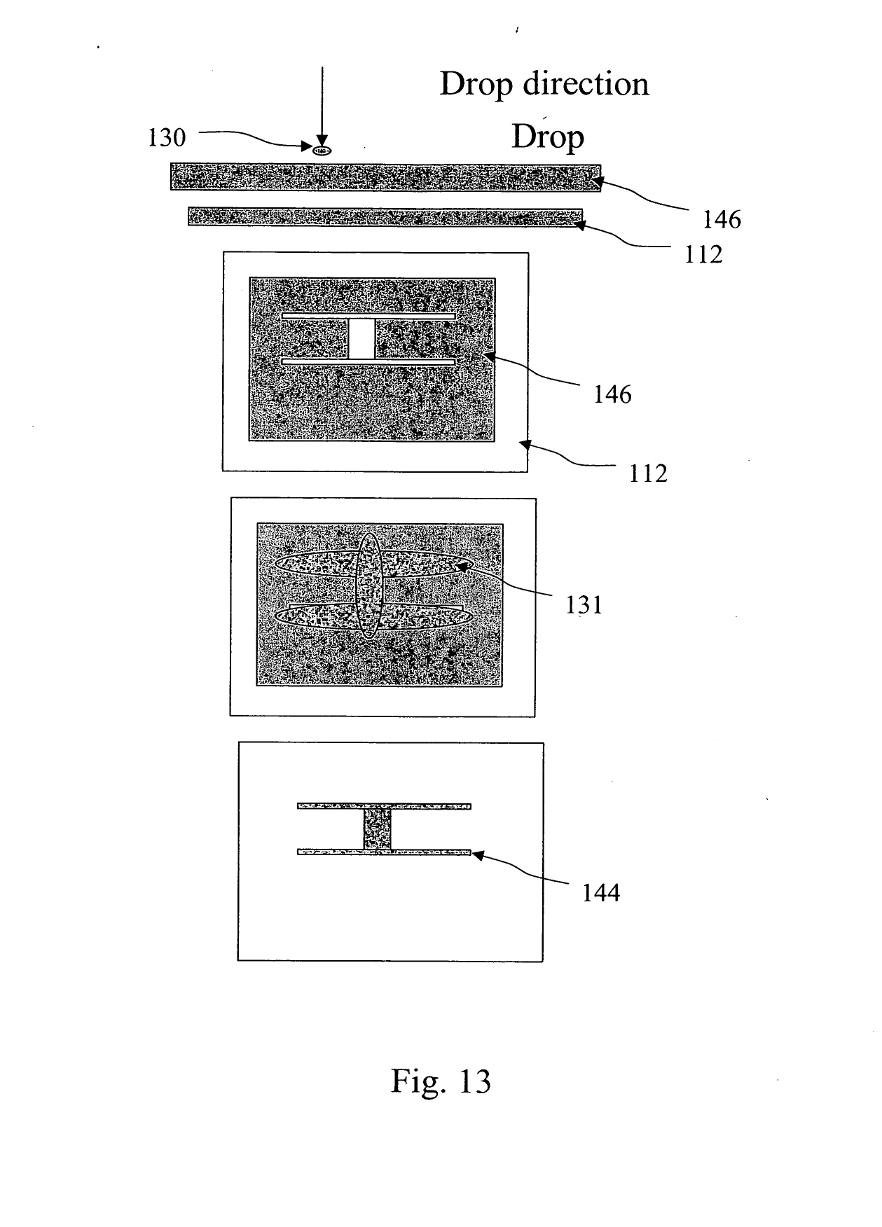

If the mask is unnecessary for patterning, the requirements on line width and accuracy of the mask can be relaxed. As such a proximity mask become sufficient as is shown in FIG. 13. In FIG. 13 the mask 146 is displaced from the substrate 112 leaving a gap. Patterning occurs as in FIG. 12 with the exception tat more care is taken to confine the ink 131 to the relative image of the pattern 148.

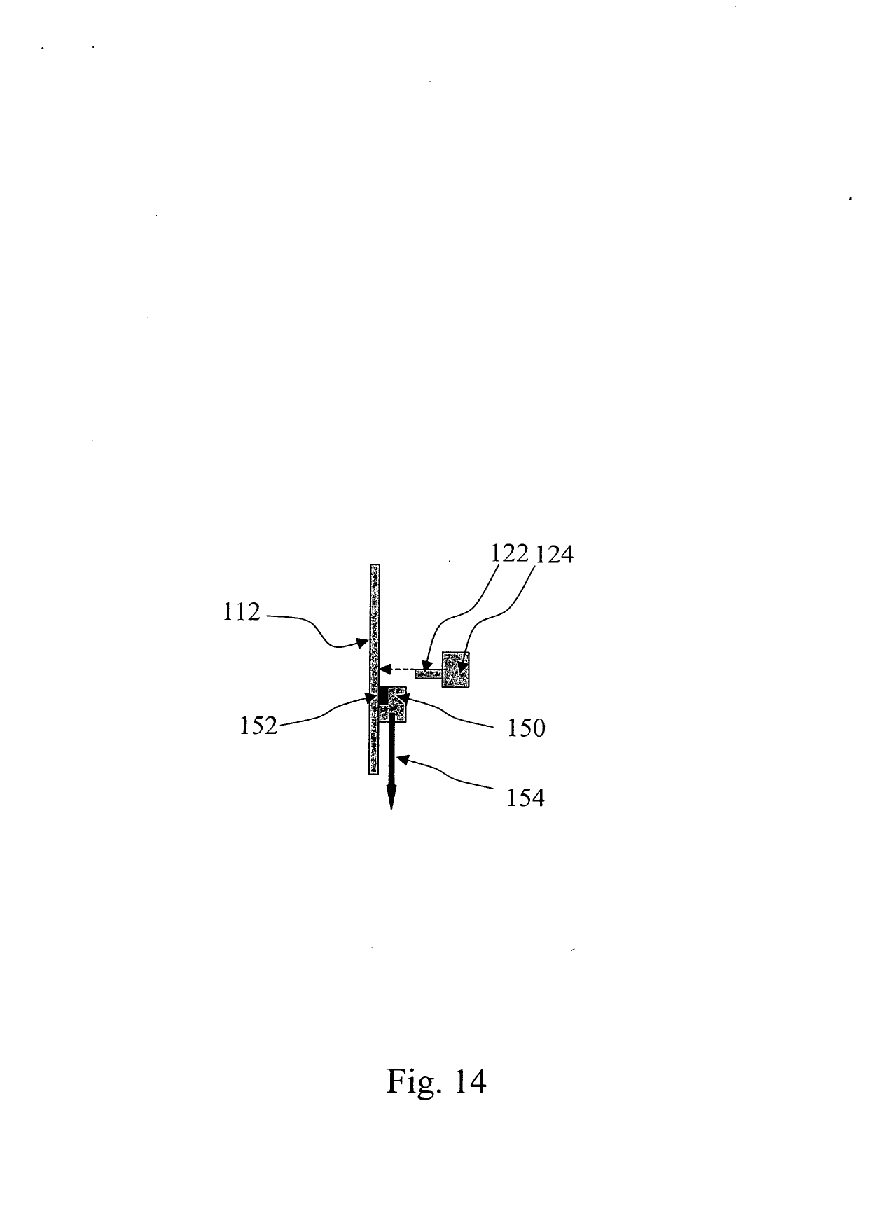

A proximity mask may be as simple as a moving bar 150 along an axis 154 where drip may occur as shown in FIG. 14. A drip bar 150 may even contain a receptacle or ink collector 152 to allow for ink recycle.

Ink recycling and disposal are an important part of the system particularly of a continuous inkjet based system. Consequently a guttering system, not shown, for collecting and removing non-adhered drops is desirable. The moving bar is an excellent approach. Alternatively a sink can be placed in the system to collect free ink.

Composite Process

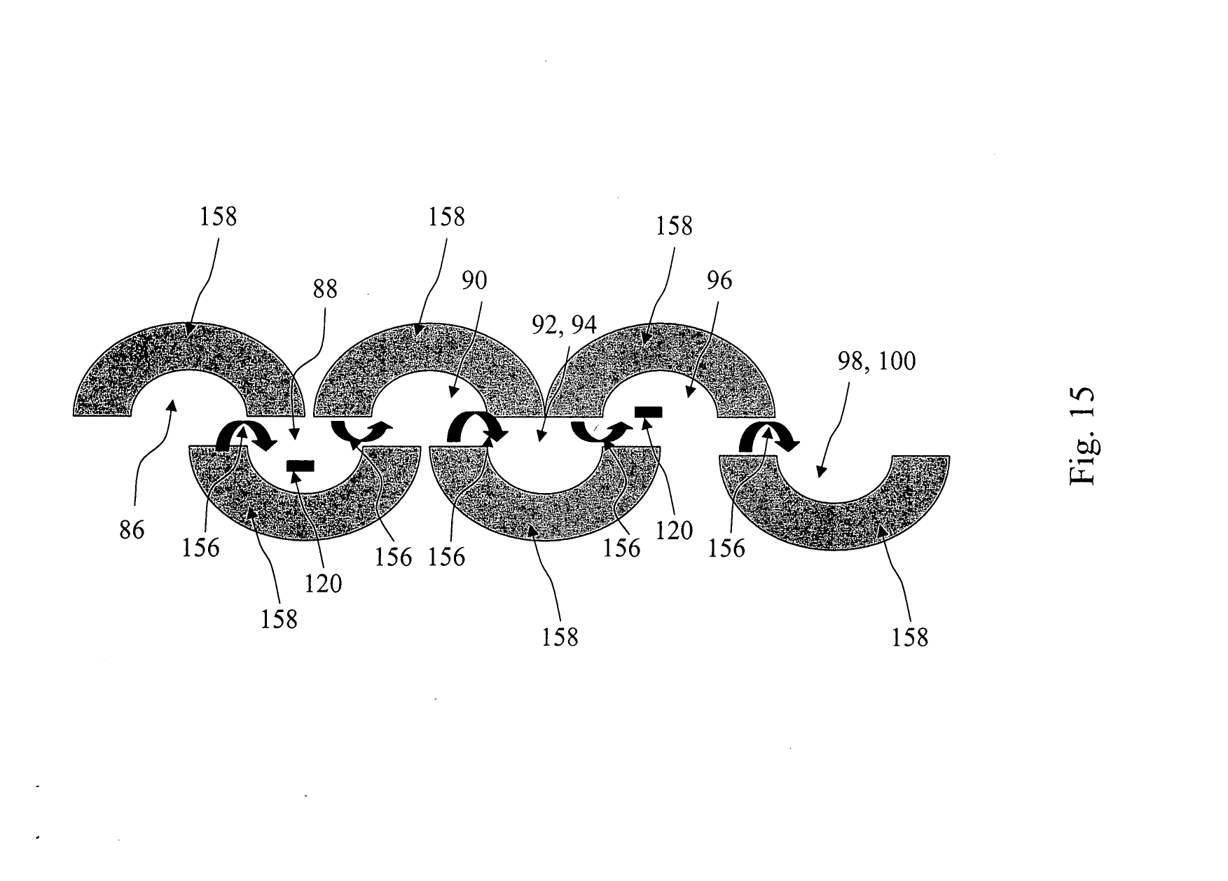

An example of composite process is shown in FIG. 15. The substrate is moving along a curved web following the process flow outlined in FIG. 4. Patterning and deposition equipment such as the inkjet head 120 reside in the space subtended by the arc defined by the substrate curvature. In order to maintain the outward face of the substrate, the substrate is flipped 156 between web mounts 158.

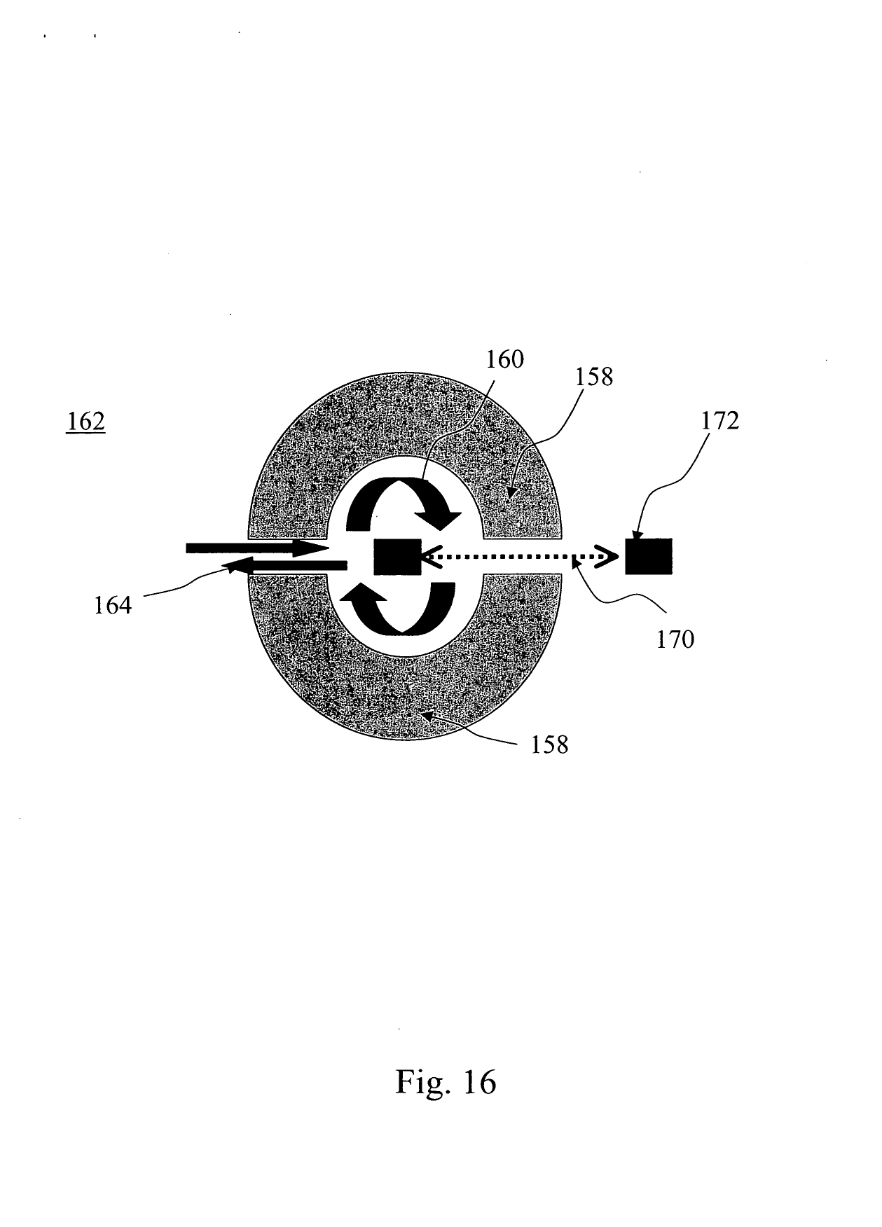

An alternate process is to contain the process within a curved enclosure 162 to allow uninterrupted motion 160 along the curve as is shown in FIG. 16. In FIG. 16 patterning occurs within a semi-enclosed combination web mounts. The web mounts are separable to allow the substrate to be placed 164 inside and to be removed. In addition, the printing equipment 172 may be permanently located 170 inside the web mounts 158 or may be placed and extracted from the apparatus as needed.

An alternate means by which to insert and remove substrate or equipment is to do so along the axis normal to the plane shown in FIG. 16 which we shall refer to as the axial length of the web mounts.

The hybrid or possible all-printed methods for TFTs on curved surface can be used for but not limited to back plane fabrication of curved active-matrix display and X-ray sensor arrays in digital radiography applications for curved body, such as dental radiography, mammography, etc.

The invention has been described in detail with particular reference to certain preferred embodiments thereof, but it will be understood that variations and modifications can be effected within the scope of the invention.

### Parts List

10 back-channel-etch-type amorphous silicon thin-film transistor
12 substrate
14 first passivation layer
16 first metal layer
18 insulator layer
20 first semiconductor layer
22 second semiconductor layer
22a patterned second semiconductor layer
22b patterned second semiconductor layer
24 second metal layer
24a patterned second metal layer
24b patterned second metal layer
26 back channel etched area
28 second passivation layer
30 photolithography-based amorphous silicon thin-film transistor process flow
32 substrate cleaning
34 first passivation layer deposition
36 first metal layer deposition
38 photolithography patterning of first metal layer
40 PECVD insulator, first and second semiconductor layers deposition
42 photolithography patterning of first and second semiconductor layers
44 photolithography patterning of insulator layer
46 second metal layer deposition
48 photolithography patterning of second metal layer
50 back channel etching
52 second passivation layer deposition
54 substrate formation
60 photolithography-based amorphous silicon thin-film transistor process flow
62 substrate
64 first passivation layer
66 first metal layer
68 insulator layer
70 first semiconductor layer
72 second semiconductor layer
72a patterned second semiconductor layer
72b patterned second semiconductor layer
74 second metal layer
74a patterned second metal layer
74b patterned second metal layer
78 second passivation layer
80 hybrid (conventional and printed) amorphous silicon thin-film transistor
82 substrate formation
84 substrate cleaning
86 first passivation layer deposition
88 first metal layer printing in pattern
90 PECVD insulator, first and second semiconductor layers deposition
92 photolithography patterning of first and second semiconductor layers
94 photolithography patterning of insulator layer
96 second metal layer printing in pattern
98 back channel etching
100 second passivation layer deposition
102 pre-curved (spherical and cylindrical) substrate
110 moving inkjet printing head
112 substrate
114 first passivation layer
116 first metal layer
118 wax mask
120 printhead
122 ink exit or nozzle
124 control element
128 trajectory
130 ink drop
131 ink
132 deflected drop fracture
134 heated mount or roll
140 laser
144 pattern on substrate
146 mask
148 pattern region
150 bar
152 ink collector
154 direction of bar motion
156 substrate flip
158 web mount
160 uninterrupted motion
162 curved enclosure
164 direction of substrate motion
170 printing equipment motion
172 printing equipment

1. A method for in-line fabrication of curved surface transistors comprising:
forming a flexible substrate into a predetermined shape;
depositing a first passivation layer;
depositing a first metal layer in a first pattern;
depositing an insulator layer in a second pattern;
depositing a first semiconductor layer in a third pattern;
depositing a second semiconductor layer in a fourth pattern;
depositing a second metal layer in a fifth pattern; and
depositing a second passivation layer in a sixth pattern.

2. A method as in claim 1 wherein said first passivation layer is printed with inkjet.

3. A method as in claim 1 wherein at least some regions of said substrate is heated.

4. A method as in claim 1 wherein said first passivation layer is deposited in vacuum.

5. A method as in claim 1 wherein said first metal layer is printed with inkjet.

6. A method as in claim 5 wherein drop trajectories from said inkjet are determined by a curvature of said substrate.

7. A method as in claim 5 wherein placement of nozzles of said inkjet are determined by a curvature of said substrate.

8. A method as in claim 5 wherein a curvature of a printhead of said inkjet is determined by a curvature of said substrate.

9. A method as in claim 5 wherein a mask is placed in contact with said substrate.

10. A method as in claim 5 wherein a mask is placed in close proximity to said substrate.

11. A method as in claim 5 wherein a movable bar is placed in close proximity to said substrate.

12. A method as in claim 11 wherein said movable bar contains a receptacle.

13. A method as in claim 5 wherein a polymer mask is employed.

14. A method as in claim 1 wherein said insulating layer is deposited through plasma enhanced chemical vapor deposition.

15. A method as in claim 1 wherein said insulating layer is pattern through use of a inkjet printed wax mask.

16. A method as in claim 1 wherein said insulating layer is pattern through use of a photomask.

17. A method as in claim 1 wherein said first semiconducting layer is deposited through plasma enhanced chemical vapor deposition.

18. A method as in claim 1 wherein said first semiconducting layer is pattern through use of a inkjet printed wax mask.

19. A method as in claim 1 wherein said first semiconducting layer is pattern through use of a photomask.

20. A method as in claim 1 wherein said second semiconducting layer is deposited through plasma enhanced chemical vapor deposition.

21. A method as in claim 1 wherein said second semiconducting layer is pattern through use of a inkjet printed wax mask.

22. A method as in claim 1 wherein said second semiconducting layer is pattern through use of a photomask.

23. A method as in claim 1 wherein said second metal layer is printed with inkjet.

24. A method as in claim 1 wherein a polymer mask is employed.

25. A method as in claim 1 wherein the second metal layer is used as a mask for the etching of a back channel.

26. A method as in claim 1 wherein said second passivation layer is printed with inkjet.

27. A method as in claim 1 wherein said second passivation layer is deposited in vacuum.

28. A method for fabrication of curved surface transistors comprising:
forming a flexible substrate into a predetermined shape;
supporting said substrate in said flexible shape;
depositing a first passivation layer uniformly;
printing a first metal layer in a first pattern;
depositing an insulator layer in a second pattern;
depositing a first semiconductor layer in a third pattern;
depositing a second semiconductor layer in a fourth pattern;
printing a second metal layer in a fifth pattern; and
depositing a second passivation layer in a sixth pattern.

29. A method as in claim 28 wherein the printing method is inkjet printing.

30. A method as in claim 28 wherein the inkjet head is directed in path determined by a contour of the predetermined substrate shape.

31. A method as in claim 28 wherein the nozzles are directed in a path determined by a contour of the predetermined substrate shape

32. A method as in claim 28 wherein the substrate is held at an elevated temperature.

33. A method as in claim 28 where the substrate is positioned such that material that does not adhere is removed.

34. A method as in claim 28 where the position of the substrate is altered for each deposition step.

35. A method as in claim 28 wherein said fabrication is in-line.

36. A method as in claim 28 wherein drops from said inkjet printer are directed in a contour of said predetermined shape.

37. A method as in claim 28 wherein a seventh layer comprised of a scintillator material is applied.

38. A method as in claim 28 wherein a seventh layer comprised of a material selected from a group comprising emissive display material, reflective display material is applied.

39. A method for in-line fabrication of a curved surface transistors comprising:
forming a flexible substrate into a predetermined shape;
supporting said substrate in said flexible shape;
depositing a first uniform passivation layer;
printing a first metal layer in a first pattern;
depositing an insulator layer in a second pattern;
depositing a first semiconductor layer in a third pattern;
depositing a second semiconductor layer in a fourth pattern;
printing a second metal layer in a fifth pattern; and
depositing a second uniform passivation layer.

40. A method as in claim 39 wherein the printing method is continuous.

41. A method as in claim 39 wherein said in-line method is a drum printer.

42. A method as in claim 39 wherein the substrate is held at elevated temperature.

43. A method as in claim 39 where the substrate is positioned such that material that does not adhere is removed.

44. A method as in claim 39 where the position of the substrate is altered for each deposition step.

45. A method for fabrication of a curved surface transistors comprising:
forming a flexible substrate into a predetermined shape;
supporting said substrate in said predetermined shape;
depositing a first uniform passivation layer;
applying a first wax mask over said first uniform passivation layer;
printing a first metal layer in a first pattern;
removing said first wax mask;
depositing a first insulator layer;
depositing a first semiconductor layer;
depositing a second semiconductor layer;
forming a second pattern in said first and second semiconductor layer;
forming a third pattern in said insulator layer;
applying a second wax mask;
printing a second metal layer in a fourth pattern;
removing said second wax mask;
removing said second semiconductor layer in a back channel region;
depositing a second uniform passivation layer; and
forming a fifth pattern in said second uniform passivation layer.

46. A method for fabrication as in claim 45 wherein said first and second semiconductor layers are amorphous silicon.

47. A method for fabrication as in claim 45 wherein said first insulator layer is a single layer selected from a group comprised amorphous silicon nitride or amorphous silicon oxide.

48. A method as in claim 45 wherein said first insulator layer is a double layer of said amorphous silicon nitride and silicon oxide.

49. An apparatus for in-line fabrication of transistors on a curved surface of a flexible substrate comprising:
a plurality of curved web mounts wherein each web mount encloses deposition equipment;
a first curved web mount wherein first deposition equipment deposits a passivation layer on said substrate;
a second curved web mount wherein second deposition equipment deposits a first metal layer in a first pattern;
a third curved web mount wherein third deposition equipment deposits an insulator layer, a first semiconductor layer, and a second semiconductor layer;
a fourth curved web mount wherein fourth deposition equipment pattern said first and second semiconductor layer in a second pattern;
a fifth curved web mount wherein fifth deposition equipment deposits a second metal layer in a third pattern; and
a sixth curved web mount wherein sixth deposition equipment etches and passivates.

50. An apparatus as in claim 49 wherein said substrate is flipped between each of said curved web mounts.

51. An apparatus for in-line fabrication of transistors on a curved surface of a flexible substrate comprising:
a pair of separable web mounts;
a plurality of deposition equipments comprising;
a first deposition equipment which deposits a passivation layer on said substrate;
a second deposition equipment which deposits a first metal layer in a first pattern;
a third deposition equipment which deposits an insulator layer, a first semiconductor layer, and a second semiconductor layer;
a fourth deposition equipment which pattern said first and second semiconductor layer in a second pattern;
a fifth deposition equipment which deposits a second metal layer in a third pattern; and
a sixth which deposition equipment etches and passivates.

52. An apparatus as in claim 51 wherein said plurality of deposition equipments are enclosed by said separable web mounts.

53. An apparatus as in claim 52 wherein said plurality of deposition equipments are movable into and out of said separable web mounts.

54. An apparatus as in claim 51 wherein said flexible substrate is inserted along an axis formed by said separable web mounts.

55. An apparatus as in claim 51 wherein said separable web mounts are separated prior to insertion or removal of said flexible substrate.
